(19) United States
(12) Patent Application Publication
(10) Pub. No.: US 2005/0045904 A1
(43) Pub. Date: Mar. 3, 2005

(54) Light emitting diode with high heat dissipation

(76) Inventor: Hsing Chen, Kukou Township (TW)

Correspondence Address: PRO-TECHTOR INTERNATIONAL SERVICES, 20775 Norada Court, Saratoga, CA, 95070-3018, US

(21) Appl. No.: 10/870,726

(22) Filed: Jun. 16, 2004

(30) Foreign Application Priority Data
Sep. 1, 2003 (TW) 092124194

(51) Int. Cl. H01L 23/544

(52) U.S. Cl. 257/100

(57) ABSTRACT

A light emitting diode with high heat dissipation includes a printed circuit board, a conductive material, a LED chip, and a compound resin. The printed circuit board has an upper surface and a lower surface opposite to the upper surface. A via hole penetrated from the upper surface to the lower of the printed circuit board. The upper surface of the printed circuit board is formed with electrodes. The conductive material is filled into the via hole of the printed circuit board. The LED chip is mounted on the upper surface of the printed circuit board and is contacted the conductive material. The compound resin encapsulated on the LED chip.

### BACKGROUND OF THE INVENTION

1. Field of the invention

The invention relates to a light emitting diode with high heat dissipation, and in particular to a light emitting diode that is easy to be fabricated and capable of increasing lifetime of the product.

2. Description of the Related Art

Referring to FIG. 1, a conventional light emitting diode includes a printed circuit board 4, a LED chip 1, and a compound resin 9. The printed circuit board 4 is formed with electrode 7. The LED chip 1 is mounted on the printed circuit board 4, and electrically connected to the electrode 7 of the printed circuit board 4 by wires 3. The LED chip 1 is formed with pads 2, which is encapsulated by compound resin 9. Because of the poor thermal conductivity of the printed circuit board 4, the heat energy generated by LED chip 1 when applied a higher current may not be dissipated, thus, it is a conventional light emitting diode may not be manufactured to obtain higher current.

It is very important how to obtain high heat dissipation LED, and in particular to a white light emitting diode that may be produced to generate higher heat energy, therefore, the heat dissipation effect is very important.

### SUMMARY OF THE INVENTION

An objective of the invention is to provide a light emitting diode with high heat dissipation to prolong its durability and lifetime effectively.

Another objective of the invention is to provide a light emitting diode that is easy to be fabricated.

To achieve the above-mentioned objective, the invention includes a printed circuit board, a conductive material, a LED chip, and a compound resin. The printed circuit board has an upper surface and a lower surface opposite to the upper surface, and via hole penetrating the printed circuit board from the upper surface to the lower surface. The conductive material is filled into the hole of the printed circuit board. The LED chip is formed with bonding pads and is mounted on the upper surface of the printed circuit board and is connected the conductive material. The LED chip is encapsulated by compound resin.

Therefore, the heat energy generated by LED chip 4 when applied a higher current can be dissipated, so that the durability and lifetime of the light emitting diode can be prolonged effectively.

### BRIEF DESCRIPTION OF THE DRAWINGS

FIG. 1 is a cross-sectional view showing a conventional light emitting diode.

FIG. 2 is the first schematic illustration showing a light emitting diode with high heat dissipation of the present invention.

FIG. 3 is the second schematic illustration showing a light emitting diode with high heat dissipation of the present invention.

FIG. 4 is the third schematic illustration showing a light emitting diode with high heat dissipation of the present invention.

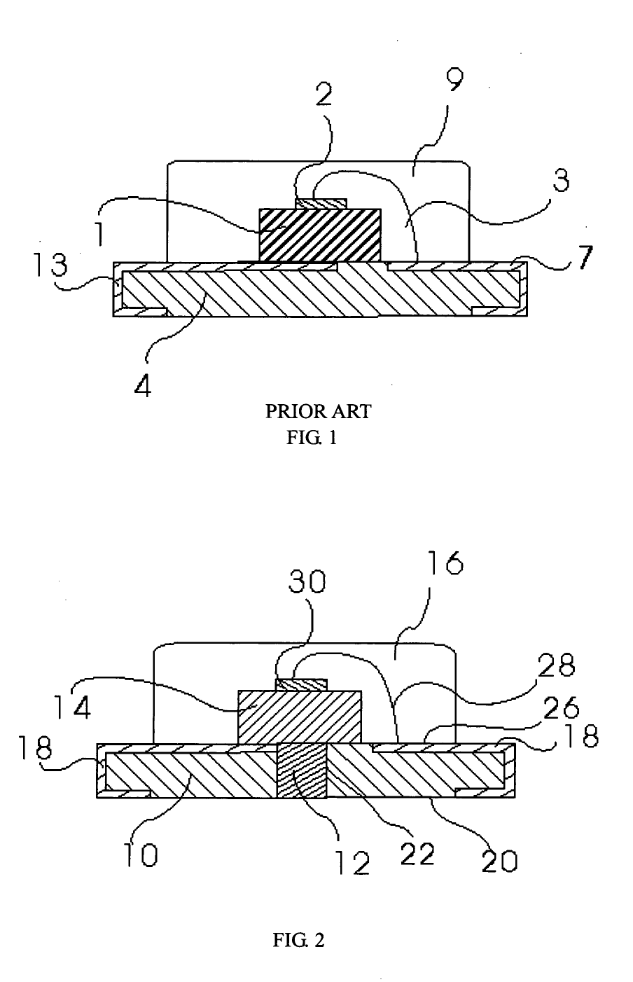

### DETAILED DESCRIPTION OF THE INVENTION

Please refer to FIG. 2, a light emitting diode with high heat dissipation of the present invention includes a printed circuit board 10, a conductive material 12, an LED chip 14, and a compound resin 16.

The printed circuit board 10 has an upper surface 18 and a lower surface 20 opposite to the upper surface 18, the upper surface 18 is formed with electrodes 26. A via hole 22 is penetrated from the upper surface 18 to the lower surface 20 of the printed circuit board 10.

The conductive material 12 is copper paste or silver paste or tin paste, which is filled into via hole 22 of the printed circuit board 10.

The LED chip 14 is mounted on the upper surface 18 of the printed circuit board 10 and is connected the conductive material 12. The LED chip 14 is formed with bonding pads that is 24 electrically connecting to the electrodes 26 of the printed circuit board 10 by wires 28.

The compound resin 16 is an epoxy-molded compound, which encapsulated the LED chip and wires 28.

Therefore, the heat energy generated by LED chip 4 may be dissipated through the conductive material 12, so that the durability and lifetime of the light emitting diode may be prolonged effectively.

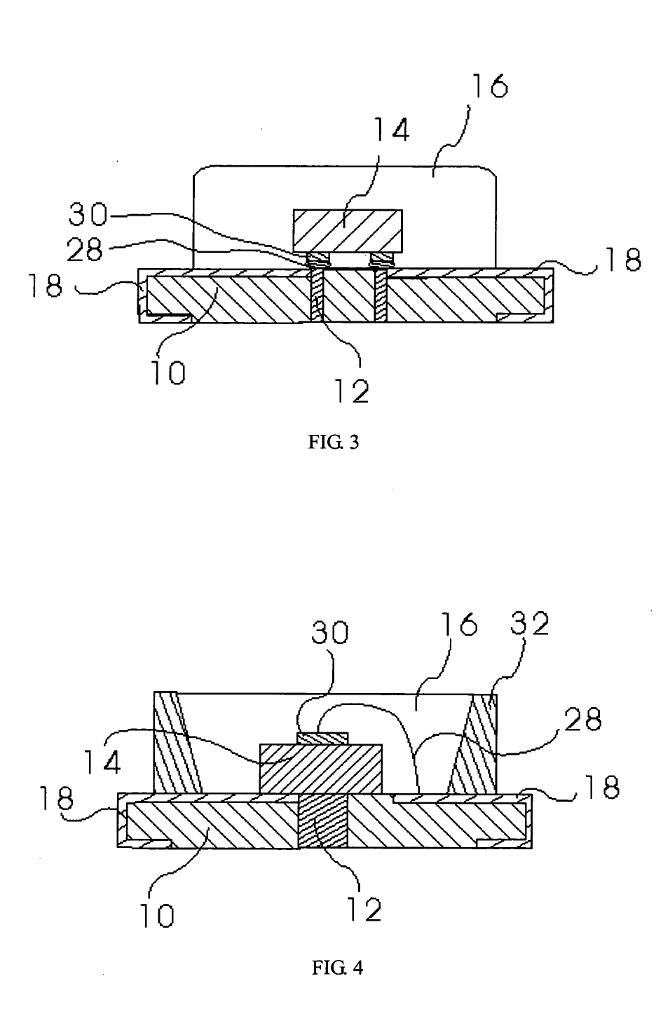

Please refer FIG. 3, the second schematic illustration showing a light emitting diode with high heat dissipation of the present invention includes a printed circuit board 10, a conductive material 12, an LED chip 14, and a compound resin 16.

The conductive material 12 comprises two conductive metals, which are filled into the via hole 22 of the printed circuit board 10. Two metal balls 28 are mounted above the conductive metal 12. The LED chip 14 is formed with bonding pads 30, which are electrically connected to the metal balls 28 in the flip-chip structure.

Therefore, the heat energy generated by the LED chip 14 may be dissipated effectively through the conductive metal, so that the durability and lifetime of the light emitting diode may be prolonged effectively.

Please refer to FIG. 4, the third schematic illustration showing a light emitting diode with high heat dissipation of the present invention includes a printed circuit board 10, a conductive material 12, an LED chip 14, a compound resin 16, and a transparent paste 32.

Wherein the transparent paste 32 is covered at the periphery of the compound resin 16, so that the emitted light from the LED chip 14 is emitted through the transparent paste 32 and the surface of the printed circuit board 10.

Therefore, the heat energy generated by the LED chip 14 may be dissipated effectively through the conductive material, so that the durability and lifetime of the light emitting diode may be prolonged.

While the invention has been described by the way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A light emitting diode with high heat dissipation, the light emitting diode comprising:
a printed circuit board having an upper surface and a lower surface opposite to the upper surface, at least a via hole penetrated from the upper surface to the lower, the upper surface of the printed circuit board, which is formed with electrodes;
a conductive material being filled into the via hole of the printed circuit boar, the conductive material comprises copper paste or silver paste or tin paste;
a LED chip mounted on the upper surface of the printed circuit board and is connected the conductive material, the LED chip formed with bonding pads, which are electrically connecting to the electrodes of the printed circuit board; and
a compound resin being encapsulated the LED chip.

2. The light emitting diode with high heat dissipation according to claim 1, wherein the bonding pads of LED chip are electrically connected to the electrodes of the printed circuit board by wires.

3. The light emitting diode with high heat dissipation according to claim 1, wherein the bonding pads of LED chip are electrically connected to the electrodes of the printed circuit board in the flip-chip structure.

4. The light emitting diode with high heat dissipation according to claim 1, wherein the compound resin is an epoxy-molded compound.
